(19) United States
(12) Patent Application Publication
(10) Pub. No.: US 2026/0126674 A1
(43) Pub. Date: May 7, 2026

(54) ELECTRO-OPTO-ACOUSTIC COMPOSITION AND ELECTRO-OPTO-ACOUSTIC DEVICE

(71) Applicant: Korea University Of Technology And Education Industry-University Cooperation Foundation, Cheonan-si (KR)

(72) Inventors: Jin Woo BAE, Seoul (KR); Seung Ju OH, Cheonan-si (KR); Seungeun Choi, Cheonan-si (KR)

(73) Assignee: Korea University Of Technology And Education Industry-University Cooperation Foundation, Cheonan-si (KR)

(21) Appl. No.: 19/275,997

(22) Filed: Jul. 22, 2025

(30) Foreign Application Priority Data
Nov. 4, 2024 (KR) 10-2024-0154324

(51) Int. Cl. G02F 1/00; C09K 11/02; C09K 11/58; G02F 1/01

(52) U.S. Cl. CPC G02F 1/0072; C09K 11/025; C09K 11/584; G02F 1/0102

(57) ABSTRACT

The present disclosure relates to an electro-opto-acoustic composition and an electro-opto-acoustic device, wherein, by adding a non-ionic surfactant, it is possible to improve a dielectric constant while simultaneously improving electroluminescence performance, and the electro-opto-acoustic composition according to an embodiment of the present disclosure includes a stretchable silicone rubber, a non-ionic surfactant, and copper-doped zinc sulfide (ZnS:Cu).

### CROSS-REFERENCE TO RELATED APPLICATION

This application claims priority to Korean Patent Application No. 10-2024-0154324 filed on Nov. 4, 2024 and all the benefits accruing therefrom under 35 U.S.C. § 119, the contents of which are incorporated by reference in their entirety.

### BACKGROUND

The present disclosure relates to an electro-opto-acoustic composition and an electro-opto-acoustic device. By adding a non-ionic surfactant, it is possible to improve a dielectric constant while simultaneously improving electroluminescence performance.

The present disclosure is the result (RS-2024-00348475) of research conducted with the support of the National Research Foundation of Korea with the funding from the government (Ministry of Science and ICT).

With the recent development of wearable electronic devices, electro-opto-acoustic devices have attracted attention as a new type of display. Since typical displays have been limited to a function of transferring primarily visual information, there has been an emerging need for multi-functional displays that combine sound and emission functions to enrich interaction with users.

Typical electroluminescent (EL) devices have attracted considerable attention as devices having a simple structure, being lightweight, having a long lifespan, and having excellent deformability. Such devices are primarily based on silver nanowires and highly conductive materials, thereby showing high luminance when a voltage is applied, but have limitations in terms of stretchability. In addition, hydrogel electrodes, which are typical flexible electrodes, provide high stretchability, but are sensitive to changes in humidity and temperature, and thus, have a problem in that the performance is unstable.

Accordingly, research has been conducted to develop an electro-opto-acoustic device which simultaneously satisfies flexibility and emission performance. However, it has been difficult for typical electro-opto-acoustic devices to have both emission performance and flexibility.

### PRIOR ART DOCUMENT

### Patent Literature

Korean Registered Patent Publication No. 10-2419272

### SUMMARY

The present disclosure provides an electro-opto-acoustic composition and an electro-opto-acoustic device, both having a high dielectric constant and excellent electroluminescence performance.

The present disclosure also provides reduced sensitivity to humidity and temperature, and provides electrical stability.

The present disclosure also provides a stable operation without degradation in emission and acoustic performance even at a stretchability of 200% or greater.

In accordance with an exemplary embodiment of the present disclosure, an electro-opto-acoustic composition includes a stretchable silicone rubber, a non-ionic surfactant, and copper-doped zinc sulfide (ZnS:Cu).

The stretchable silicone rubber may be Ecoflex silicone rubber.

The non-ionic surfactant may include octylphenol ethoxylate.

The content of the non-ionic surfactant may be 0.5 parts by weight to 1.5 parts by weight based on 100 parts by weight of the stretchable silicone rubber.

The content of the copper-doped zinc sulfide may be 150 parts by weight to 250 parts by weight based on 100 parts by weight of the stretchable silicone rubber.

In accordance with another exemplary embodiment of the present disclosure, a method for manufacturing an electro-opto-acoustic layer includes mixing a stretchable silicone rubber (Ecoflex), a non-ionic surfactant (Triton X), and copper-doped zinc sulfide (ZnS:Cu) to prepare a mixture, coating the mixture to form a coating layer, and drying the coating layer.

In the mixture, the content of the non-ionic surfactant may be 0.5 parts by weight to 1.5 parts by weight based on 100 parts by weight of the stretchable silicone rubber.

In the mixture, the content of the copper-doped zinc sulfide may be 150 parts by weight to 250 parts by weight based on 100 parts by weight of the stretchable silicone rubber.

In accordance with another exemplary embodiment of the present disclosure, an electro-opto-acoustic device includes a first electro-opto-acoustic layer disposed in one direction, a second electro-opto-acoustic layer disposed in the other direction perpendicular to the one direction and disposed to be woven with the first electro-opto-acoustic layer, first electrodes respectively disposed at one end and the other end of the first electro-opto-acoustic layer, and second electrodes respectively disposed at one end and the other end of the second electro-opto-acoustic layer.

The first and second electro-opto-acoustic layers may be as described above.

In accordance with still another exemplary embodiment of the present disclosure, a method for manufacturing an electro-opto-acoustic device includes preparing a first electrode, coating an electro-opto-acoustic composition on the first electrode to form a coating layer, disposing a second electrode on the coating layer, and curing the structure in which the first electrode, the coating layer, and the second electrode are stacked.

The electro-opto-acoustic composition may be as described above.

### BRIEF DESCRIPTION OF THE DRAWINGS

Exemplary embodiments can be understood in more detail from the following description taken in conjunction with the accompanying drawings, in which:

FIG. 1 is a flowchart of a method for manufacturing an electro-opto-acoustic layer in accordance with an exemplary embodiment of the present disclosure;

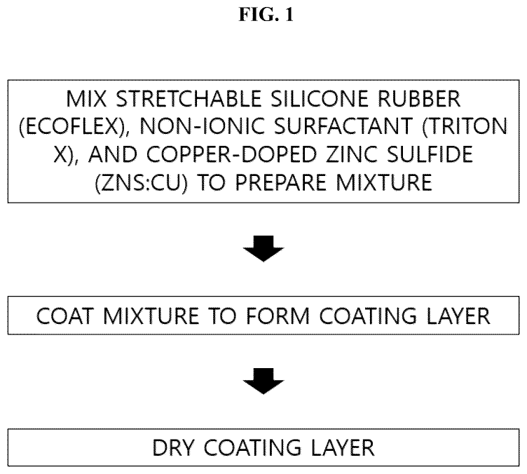

FIG. 2 is a conceptual diagram of a method for manufacturing an electro-opto-acoustic device in accordance with an exemplary embodiment of the present disclosure;

FIG. 3 is a view before and after a voltage is applied to an electro-opto-acoustic device in accordance with an exemplary embodiment of the present disclosure;

FIG. 4 shows results of measuring dielectric constants of Examples and Comparative Examples;

FIG. 5 shows results of measuring leakage currents of Manufacturing Examples;

FIG. 6 shows results of analyzing stress-strain rates of Examples and Comparative Examples;

FIG. 7 shows results of measuring luminance according to voltages of Manufacturing Examples;

FIG. 8 shows results of measuring maximum emission wavelengths according to voltages of Manufacturing Example 1;

FIG. 9 shows results of analyzing emission colors according to voltages of Manufacturing Example 1;

FIG. 10 shows results of measuring luminance according to frequencies of Manufacturing Examples;

FIG. 11 shows results of measuring maximum emission wavelengths according frequencies of Manufacturing Example 1;

FIG. 12 shows results of analyzing emission colors according to frequencies of Manufacturing Example 1;

FIG. 13 shows photographs of emission phenomena of Manufacturing Example 1 according to frequencies;

FIG. 14 shows photographs of emission phenomena of Manufacturing Example 1 after being stretched in one direction by 0% to 200% and then applied with a voltage;

FIG. 15 shows results of measuring sound pressure levels (SPLs) according to voltages of Manufacturing Examples;

FIG. 16 shows results of measuring sound pressure levels (SPLs) according to frequencies of Manufacturing Examples; and

FIG. 17 shows results of measuring sound pressure levels (SPLs) according to stretching of Manufacturing Example 1.

### DETAILED DESCRIPTION OF EMBODIMENTS

Hereinafter, preferred embodiments of the present disclosure will be described as follows with reference to the accompanying drawings. However, embodiments of the present disclosure may be modified into various other forms, and the scope of the present disclosure is not limited to the embodiments described below. In addition, the embodiments of the present disclosure are provided in order to more fully describe the present disclosure to those with average knowledge in the art.

An electro-opto-acoustic composition according to an embodiment of the present disclosure includes a stretchable silicone rubber, a non-ionic surfactant, and copper-doped zinc sulfide (ZnS:Cu).

The stretchable silicone rubber is used as a main matrix of the electro-opto-acoustic layer, and provides flexibility of an electro-opto-acoustic device. The stretchable silicone rubber has stable physical properties even at high temperatures and low temperatures, and has excellent insulation and chemical resistance.

The stretchable silicone rubber may be Ecoflex silicone rubber, PDMS-based silicone rubber, silicone gel, or the like, and preferably, may be Ecoflex silicone rubber.

In an embodiment, the Ecoflex silicone rubber may be represented by Chemical Structural Formula 1 below.

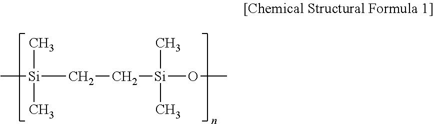

(n is a natural number)

The non-ionic surfactant improves dielectric properties of an electro-opto-acoustic layer and improves electroluminescence performance. The non-ionic surfactant changes the properties at the interface between materials, thereby allowing a luminescent material to function more efficiently. The non-ionic surfactant does not release ions, and thus, may reduce unnecessary ion interference within an emission layer, and may maintain emission and sound generation performance more stably.

The non-ionic surfactant may be any one of Triton X series, Span series, and Tween series, preferably Triton X series, and may include octylphenol ethoxylate. The Triton X series non-ionic surfactant is advantageous in improving a dielectric constant, and has excellent balance of hydrophobicity and hydrophilicity, and thus has good dispersibility. In addition, the Triton X series non-ionic surfactant is not sensitive to humidity and temperature, and thus is stable.

The content of the non-ionic surfactant may be 0.5 parts by weight to 1.5 parts by weight, preferably 0.8 parts by weight to 1.2 parts by weight, based on 100 parts by weight of the stretchable silicone rubber. If the content of the non-ionic surfactant is too low, there is no effect of improving a dielectric constant, and dispersion is non-uniform, thereby reducing performance. On the contrary, if the content is too high, the leakage current is increased, thereby reducing emission performance.

In an embodiment, the Triton X series non-ionic surfactant may be represented by Chemical Structural Formula 2 below.

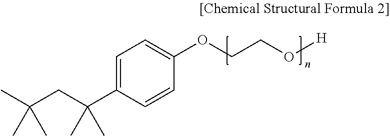

(n is a natural number)

The copper-doped zinc sulfide is used as a luminescent material, and generates light through electroluminescence when an electric field is applied. Copper ions are doped into zinc sulfide, thereby transitioning electrons to an excited state when an electric field is applied, which results in an emission phenomenon. The copper-doped zinc sulfide provides high emission efficiency in an electroluminescent device compared to other materials, and due to the doping of copper ions, electron movement is facilitated, so that brighter and clearer light may be emitted, and excellent durability and low power consumption are achieved.

The content of the copper-doped zinc sulfide may be 150 parts by weight to 250 parts by weight, preferably 180 parts by weight to 220 parts by weight, based on 100 parts by weight of the stretchable silicone rubber. If the content of the copper-doped zinc sulfide is too low, the emission intensity may be degraded, and on the contrary, if the content is too high, stretchability may be degraded and excessive heat may be generated.

In accordance with another exemplary embodiment of the present disclosure, a method for manufacturing an electro-opto-acoustic layer includes mixing a stretchable silicone rubber (Ecoflex), a non-ionic surfactant (Triton X), and copper-doped zinc sulfide (ZnS:Cu) to prepare a mixture, coating the mixture to form a coating layer, and drying the coating layer.

The preparing of the mixture is a step of preparing a base material by mixing each mixture to be evenly dispersed, thereby having uniform electrical and mechanical properties. The present step may be performed using a stirrer or the like by simultaneously or sequentially adding a stretchable silicone rubber (Ecoflex), a non-ionic surfactant (Triton X), and copper-doped zinc sulfide (ZnS:Cu). The present step may be performed at room temperature.

The content of the non-ionic surfactant in the mixture may be 0.5 parts by weight to 1.5 parts by weight based on 100 parts by weight of the stretchable silicone rubber, and the content of the copper-doped zinc sulfide in the mixture may be 150 parts by weight to 250 parts by weight based on 100 parts by weight of the stretchable silicone rubber.

The forming of the coating layer by coating the mixture is a step of coating the mixture to a predetermined thickness, thereby manufacturing an electro-opto-acoustic layer having uniform thickness and properties. The present step may be performed by a method such as doctor blade, slot die coating, spin coating, or the like, and the coating may be performed to a thickness of about 0.1 mm to about 0.5 mm. In an embodiment, the coating rate may be 20 mm/s to 50 mm/s, and before the coating, a substrate on which the mixture is to be coated may be preheated to a predetermined temperature, for example, 30° C. to 40° C.

The drying of the coating layer is a step of solidifying the coated layer, thereby forming a stable electro-opto-acoustic layer. In the present step, a silicone layer is thermally cured such that a solvent does not affect the generation of light and sound. The present step may be performed using a convection oven or vacuum oven by heating the coating layer to a predetermined temperature, for example, 80° C. to 120° C. If the drying is performed in an environment with high humidity, the uniformity of the coating layer may be degraded, so that the drying may be performed while maintaining the humidity at 30% to 40%.

In accordance with another exemplary embodiment of the present disclosure, an electro-opto-acoustic device includes a first electro-opto-acoustic layer disposed in one direction, a second electro-acoustic layer disposed in the other direction perpendicular to the one direction and disposed to be woven with the first electro-opto-acoustic layer, first electrodes respectively disposed at one end and the other end of the first electro-opto-acoustic layer, and second electrodes respectively disposed at one end and the other end of the second electro-opto-acoustic layer.

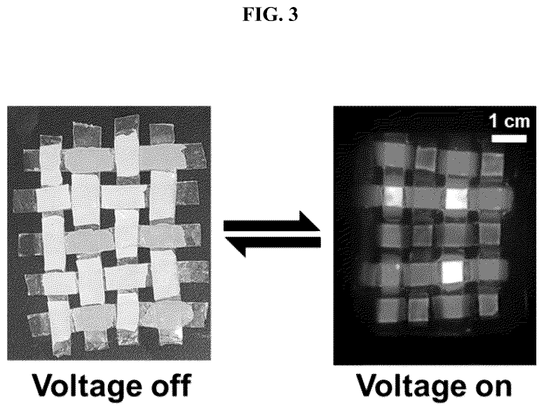

The first electro-opto-acoustic layer and the second electro-opto-acoustic layer may be disposed in a woven form with each other, and may have an overall structure similar to that of a fabric (see FIG. 3).

The first and second electro-opto-acoustic layers may be as described above.

The first electrode and the second electrode may be gel electrodes. Accordingly, flexibility may be imparted. The first electrode and the second electrode are materials having both stretchability and electrical conductivity, and are electrodes serving as ion conductors, which may be made of a polyurethane-based ion gel (PU/EMIMTFSI) or the like.

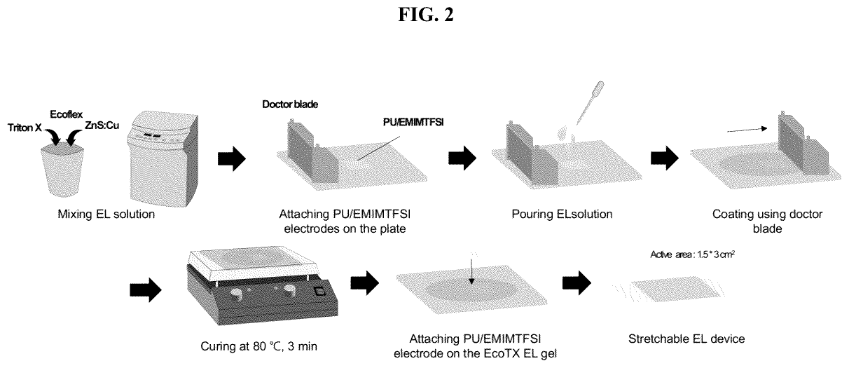

In accordance with still another exemplary embodiment of the present disclosure, a method for manufacturing an electro-opto-acoustic device includes preparing a first electrode, coating an electro-opto-acoustic composition on the first electrode to form a coating layer, disposing a second electrode on the coating layer, and curing the structure in which the first electrode, the coating layer, and the second electrode are stacked (see FIG. 2).

As described above, the first electrode and the second electrode may be gel electrodes. The preparing of the first electrode may form an electrode layer using an ion gel electrode, a silver nanowire electrode, or a metal thin film. The present step may be performed by manufacturing an electrode of an ion gel through a solution casting method. In an embodiment, the above step may be performed by mixing a polymer resin (such as PU), an ionic liquid (such as EMIMTFSI), and a solvent (such as tetrahydrofuran) and stirring the mixture, followed by evaporating the solvent.

The forming of the coating layer is a step for forming an electro-opto-acoustic layer. Through a method such as doctor blade, slot-die coating, or spin coating, the coating layer having a thickness of about 100 μm to about 500 μm may be formed using a mixture in which the above-described materials are mixed. In an embodiment, the coating rate may be 20 mm/s to 50 mm/s, and before the coating, a substrate on which the mixture is to be coated may be pre-heated to a predetermined temperature, for example, 30° C. to 40° C.

The step of disposing the second electrode on the coating layer may be similar to the step of forming the first electrode. The present step may be performed by manufacturing an electrode of an ion gel through a solution casting method. In an embodiment, the above step may be performed by mixing a polymer resin (such as PU), an ionic liquid (such as EMIMTFSI), and a solvent (such as tetrahydrofuran) and stirring the mixture, followed by evaporating the solvent.

The curing is a step of solidifying all layers and enhancing electrical properties and mechanical strength. The present step may be performed using a convection oven, a vacuum oven, or a UV curing method, and may be performed under conditions of 80° C. to 120° C.

### Examples: Manufacturing of Electro-Opto-Acoustic Layer

Example 1 (Eco TX1): 3 g of Ecoflex (Smooth on, 00-30) as a stretchable silicone rubber, 0.03 g of Triton X (Junsei) as a non-ionic surfactant, and 6 g of copper-doped zinc sulfide (Shanghai KPT Co, D502B) were added to a stirrer and stirred to prepare a mixture. The mixture was coated on a doctor blade to a thickness of 100 μm, and then heat-treated at 80° C. for 3 minutes to be cured.

Example 2 (Eco TX2): An electro-opto-acoustic layer was prepared in the same manner as in Example 1, except that 0.06 g of Triton X (Junsei) was added as a non-ionic surfactant.

Example 3 (Eco TX0.5): An electro-opto-acoustic layer was prepared in the same manner as in Example 1, except that 0.015 g of Triton X (Junsei) was added as a non-ionic surfactant.

Comparative Example 1 (Eco TX0): An electro-opto-acoustic layer was prepared in the same manner as in Example 1, except that those not containing a non-ionic surfactant were excluded.

### Manufacturing Examples: Manufacturing of Electro-Opto-Acoustic Device

Manufacturing Example 1 (Eco TX1): To tetrahydrofuran, polyurethane and EMIMTFSI were added in a weight ratio of 1:4, and then dissolved to prepare an electrode solution. The electrode solution was coated to a thickness of 800 μm on a doctor blade to form a first electrode coating layer.

3 g of Ecoflex, 0.03 g of Triton X, and 6 g of copper-doped zinc sulfide were added to a stirrer and stirred to prepare a mixture. The mixture was coated to a thickness of 100 μm on the first electrode coating layer to form a coating layer. Next, the electrode solution prepared above was coated on the coating layer to form a second electrode coating layer with a thickness of 800 μm.

The stacked coating layer was heat-treated at 80° C. for 3 minutes to be cured, thereby manufacturing an electro-opto-acoustic device composed of a first electrode—an electro-opto-acoustic layer—a second electrode.

Manufacturing Example 2 (Eco TX2): An electro-opto-acoustic device was manufactured in the same manner as in Manufacturing Example 1, except that 0.06 g of Triton X (Junsei) was added as a non-ionic surfactant.

Manufacturing Example 3 (Eco TX0.5): An electro-opto-acoustic device was manufactured in the same manner as in Manufacturing Example 1, except that 0.015 g of Triton X (Junsei) was added as a non-ionic surfactant.

Manufacturing Example 4 (Eco TX0): An electro-opto-acoustic device was manufactured in the same manner as in Manufacturing Example 1, except that a non-ionic surfactant was not added.

### Experimental Example: Measurement of Dielectric Constant

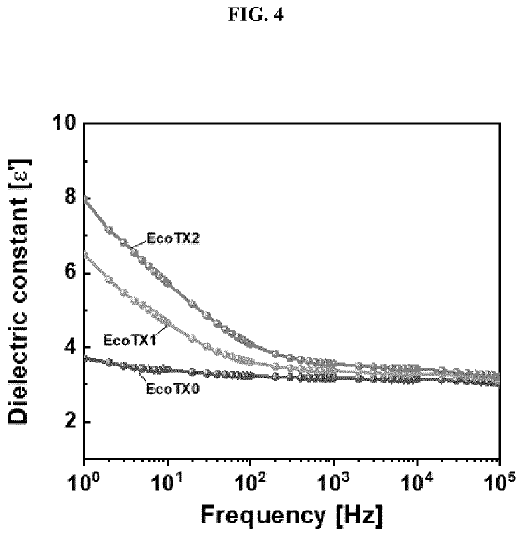

Dielectric constants of Examples and Comparative Examples were measured using an impedance analyzer, and the results are shown in FIG. 4.

Referring to FIG. 4, it can be seen that Examples each have a high dielectric constant.

### Experimental Example: Measurement of Leakage Current

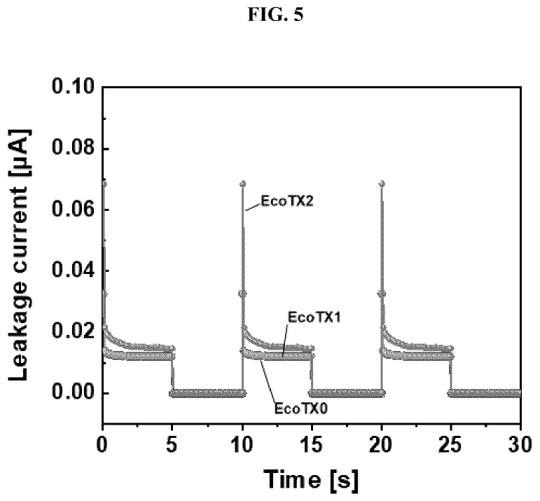

Leakage currents of Manufacturing Examples were measured using a SP240 potentiostat device of Biologics Company, and the results are shown in FIG. 5.

Referring to FIG. 5, a rapid increase in leakage current was observed in Manufacturing Example 2 (Eco TX2) in which a significant amount of Triton X was added.

### Experimental Example: Analysis of Stress-Strain

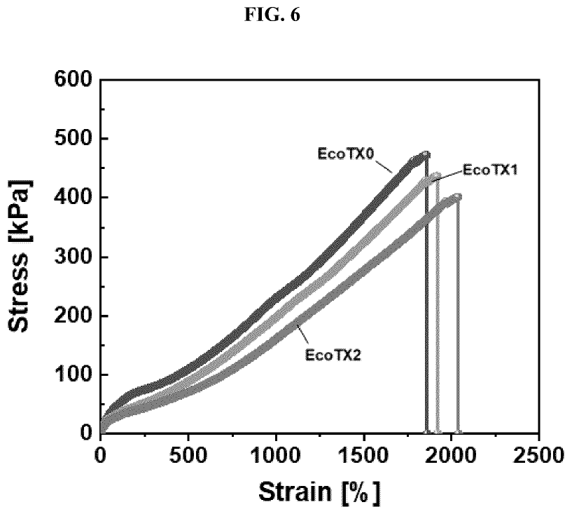

Stress-strain rates of Examples and Comparative Examples were analyzed using a H5KT universal tester of Tinius Olsen Company, and the results are shown in FIG. 6.

Referring to FIG. 6, it can be seen that the more the addition of Triton X, the greater the elongation and the lower the Young's modulus.

### Experimental Example: Measurement of Luminance According to Voltage

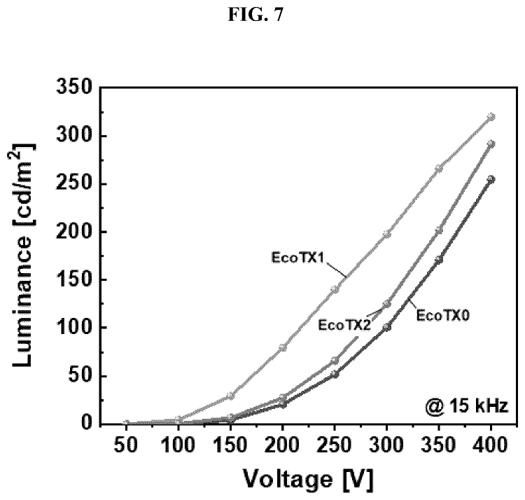

Luminance according to voltages of Manufacturing Examples was examined using a PR-655 spectroradiometer of Photoresearch Company, and the results are shown in FIG. 7.

Referring to FIG. 7, it can be seen that Manufacturing Example 1 (Eco TX1) has the best luminance. It is expected that Manufacturing Example 2 (Eco TX2) has emission efficiency which has been decreased due to a high leakage current.

### Experimental Example: Measurement of Maximum Emission Wavelength According to Voltage

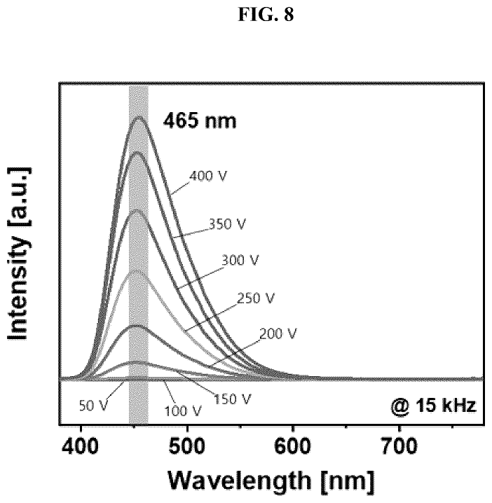

Maximum emission wavelengths according to voltages of Manufacturing Example 1 were examined using a PR-655 spectroradiometer of Photoresearch Company, and the results are shown in FIG. 8.

Referring to FIG. 8, the highest intensity was exhibited at a wavelength of 465 nm in all voltage ranges.

### Experimental Example: Measurement of Emission Color According to Voltage

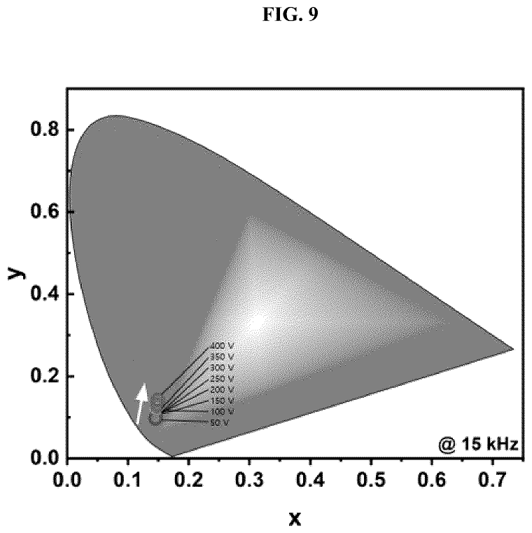

Emission colors according to voltages of Manufacturing Example 1 were analyzed using a PR-655 spectroradiometer of Photoresearch Company, and the results are shown in FIG. 9.

Referring to FIG. 9, it can be seen that as the voltage increases from 50 V to 400 V, the emission color moves closer to a blue region from a green region.

### Experimental Example: Measurement of Luminance According to Frequency

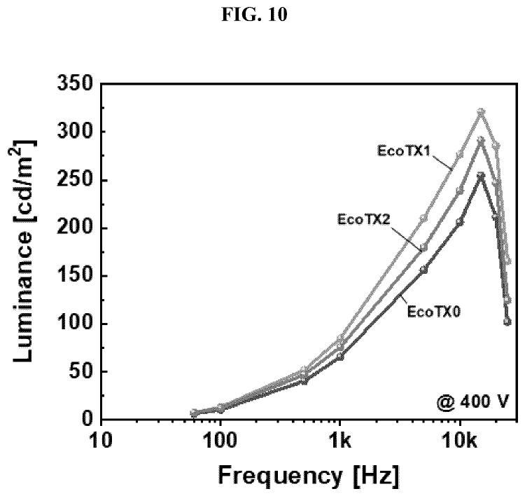

Luminance according to frequencies of Manufacturing Examples was examined using a PR-655 spectroradiometer of Photoresearch Company, and the results are shown in FIG. 10.

Referring to FIG. 10, in Manufacturing Examples, it can be seen that the luminance increases until the frequency reaches 15 kHz, but decreases thereafter. In this case, Manufacturing Example 1 (Eco TX1) exhibits the best luminance.

### Experimental Example: Measurement of Maximum Emission Wavelength According to Frequency

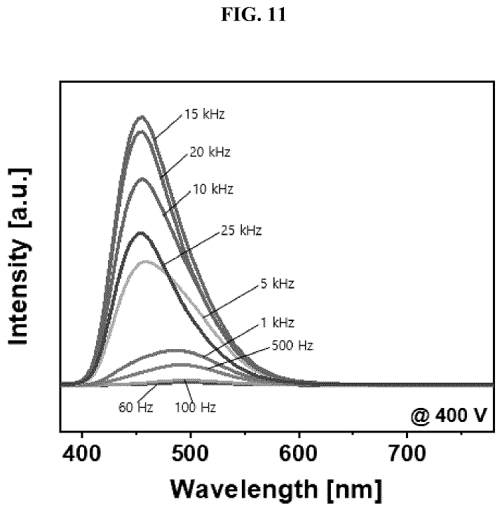

Maximum emission wavelengths according to frequencies of Manufacturing Example 1 were examined using a PR-655 spectroradiometer of Photoresearch Company, and the results are shown in FIG. 11.

Referring to FIG. 11, the highest intensity was exhibited at a frequency of 15 kHz. It can be seen that Manufacturing Example 1 exhibits the highest efficiency at a frequency of 15 kHz.

### Experimental Example: Measurement of Emission Color According to Frequency

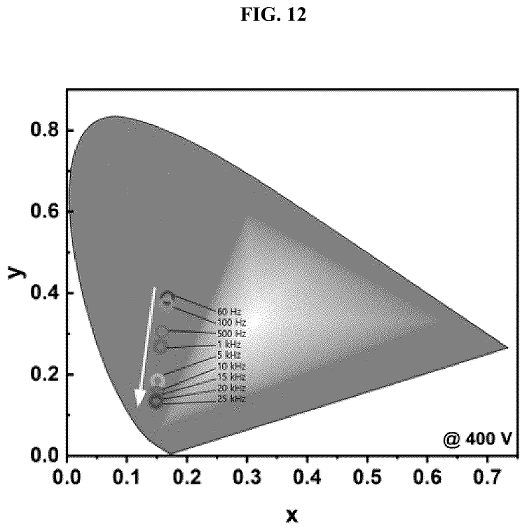

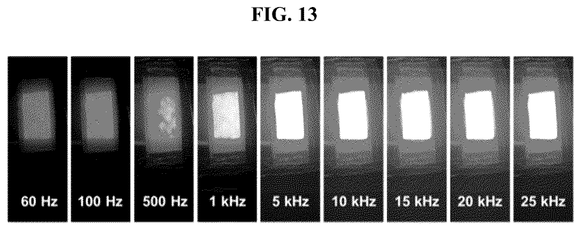

Emission colors according to frequencies of Manufacturing Example 1 were analyzed using a PR-655 spectroradiometer of Photoresearch Company, and the results are shown in FIG. 12. In addition, FIG. 13 shows photographs of emission phenomena of Manufacturing Example 1 according to frequencies.

Referring to FIG. 12, it can be seen that as the frequency increases from 60 Hz to 25 kHz, the emission color moves closer to a blue region from a green region. It can be seen that at a frequency equal to or greater than 10 kHz, the color moves to a darker blue region, and the device emits a more blue-based light at a high frequency.

### Experimental Example: Measurement of Emission Properties According to Stretching

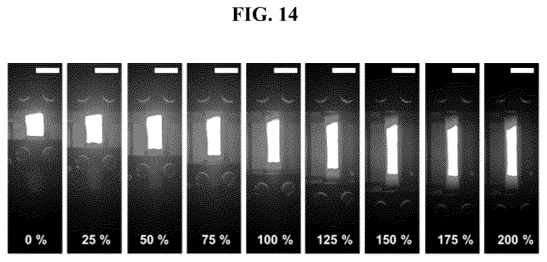

Emission phenomena were observed after stretching Manufacturing Example 1 in one direction by 0% to 200% and then applying a voltage, and the captured photographs are shown in FIG. 14.

Referring to FIG. 14, it can be seen that even with stretching, the emission efficiency is excellent.

### Experimental Example: Measurement of Sound Pressure Level According to Voltage

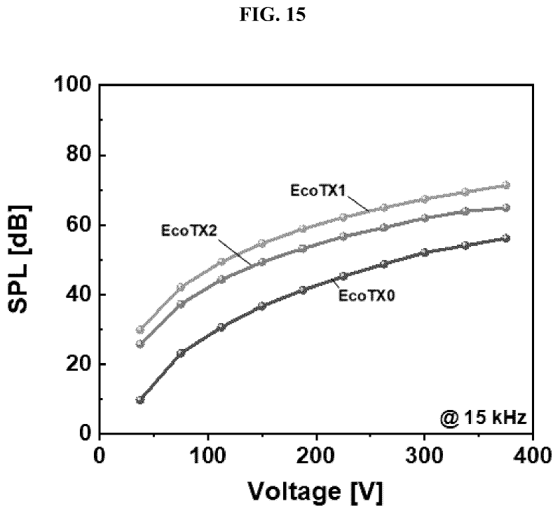

Sound pressure levels (SPLs) according to voltages of Manufacturing Examples were measured using a signal analyzer of SpectraPLUS-SC, and the results are shown in FIG. 15.

Referring to FIG. 15, it can be seen that Manufacturing Example 1 (Eco TX1) shows the best SPL

### Experimental Example: Measurement of Sound Pressure Level According to Frequency

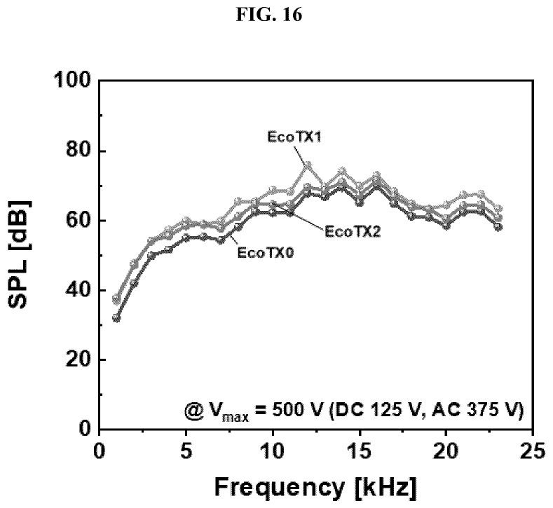

Sound pressure levels (SPLs) according to frequencies of Manufacturing Examples were measured using a signal analyzer of SpectraPLUS-SC, and the results are shown in FIG. 16.

Referring to FIG. 16, it can be seen that Manufacturing Example 1 (Eco TX1) shows the best SPL.

### Experimental Example: Measurement of Sound Pressure Level According to Stretching

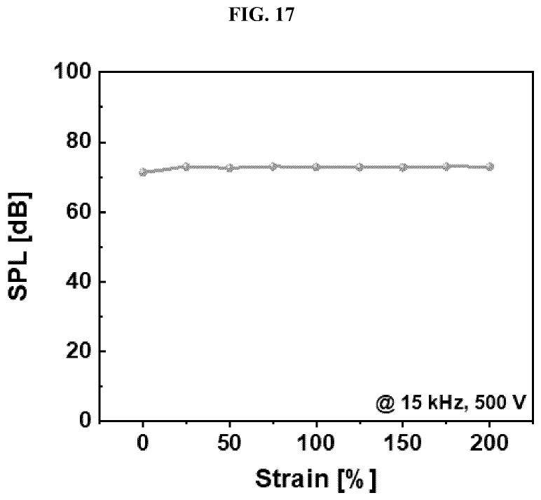

Sound pressure levels (SPLs) according to stretching of Manufacturing Examples were measured using a signal analyzer of SpectraPLUS-SC, and the results are shown in FIG. 17.

Referring to FIG. 17, it can be seen that even when the Manufacturing Example 1 (Eco TX1) was stretched up to 200%, the SPL was not affected.

The present disclosure is not limited by the above-described embodiments and the accompanying drawings, but is intended to be limited by the appended claims. Accordingly, various types of substitutions, modifications, and changes may be made by those skilled in the art within the scope not departing from the technical spirit of the present disclosure described in the claims, and these substitutions, modifications, and changes may also belong to the scope of the present disclosure.

An electro-opto-acoustic composition and an electro-opto-acoustic device in accordance with embodiments of the present disclosure have high dielectric constants and excellent electroluminescence performance.

In addition, the present disclosure reduces sensitivity to humidity and temperature, and provides electrical stability.

In addition, the present disclosure can operate stably without degradation in emission and acoustic performance even at a stretchability of 200% or greater.

Although the [Electro-opto-acoustic composition and electro-opto-acoustic device] has been described with reference to the specific embodiments, it(they) is(are) not limited thereto. Therefore, it will be readily understood by those skilled in the art that various modifications and changes can be made thereto without departing from the spirit and scope of the present disclosure defined by the appended claims.

What is claimed is:

1. An electro-opto-acoustic composition comprising:
a stretchable silicone rubber;
a non-ionic surfactant; and
copper-doped zinc sulfide.

2. The electro-opto-acoustic composition of claim 1, wherein the stretchable silicone rubber is Ecoflex silicone rubber.

3. The electro-opto-acoustic composition of claim 1, wherein the non-ionic surfactant comprises octylphenol ethoxylate.

4. The electro-opto-acoustic composition of claim 1, wherein the content of the non-ionic surfactant is 0.5 parts by weight to 1.5 parts by weight based on 100 parts by weight of the stretchable silicone rubber.

5. The electro-opto-acoustic composition of claim 1, wherein the content of the copper-doped zinc sulfide is 150 parts by weight to 250 parts by weight based on 100 parts by weight of the stretchable silicone rubber.

6. A method for manufacturing an electro-opto-acoustic layer, the method comprising:
mixing a stretchable silicone rubber (Ecoflex), a non-ionic surfactant (Triton X), and copper-doped zinc sulfide (ZnS:Cu) to prepare a mixture;
coating the mixture to form a coating layer; and
drying the coating layer.

7. The method of claim 6, wherein in the mixture, the content of the non-ionic surfactant is 0.5 parts by weight to 1.5 parts by weight based on 100 parts by weight of the stretchable silicone rubber.

8. The method of claim 6, wherein in the mixture, the content of the copper-doped zinc sulfide is 150 parts by weight to 250 parts by weight based on 100 parts by weight of the stretchable silicone rubber.

9. An electro-opto-acoustic device comprising:
a first electro-opto-acoustic layer disposed in one direction;
a second electro-opto-acoustic layer disposed in the other direction perpendicular to the one direction and disposed to be woven with the first electro-opto-acoustic layer;
first electrodes respectively disposed at one end and the other end of the first electro-opto-acoustic layer; and
second electrodes respectively disposed at one end and the other end of the second electro-opto-acoustic layer,
wherein the first and second electro-opto-acoustic layers are as described in claim 6.

10. A method for manufacturing an electro-opto-acoustic device, the method comprising:
preparing a first electrode;
coating an electro-opto-acoustic composition on the first electrode to form a coating layer;
disposing a second electrode on the coating layer; and
curing the structure in which the first electrode, the coating layer, and the second electrode are stacked,
wherein the electro-opto-acoustic composition is as described in claim 1.

11. The method of claim 10, wherein in the electro-opto-acoustic composition, the content of the non-ionic surfactant is 0.5 parts by weight to 1.5 parts by weight based on 100 parts by weight of the stretchable silicone rubber.

12. The method of claim 10, wherein in the electro-opto-acoustic composition, the content of the copper-doped zinc sulfide is 150 parts by weight to 250 parts by weight based on 100 parts by weight of the stretchable silicone rubber.
